(19) United States
(12) Patent Application Publication
(10) Pub. No.: US 2012/0038495 A1
(43) Pub. Date: Feb. 16, 2012

(54) OPERATION FEELING IMPARTING TYPE TRACKBALL DEVICE

(75) Inventor: Shinji ISHIKAWA, Miyagi-ken (JP)

(73) Assignee: Alps Electric Co., Ltd., Ota-ku (JP)

(21) Appl. No.: 13/207,967

(22) Filed: Aug. 11, 2011

(30) Foreign Application Priority Data
Aug. 12, 2010 (JP) 2010-180997

(51) Int. Cl. H03K 17/94

(52) U.S. Cl. 341/20

(57) ABSTRACT

A trackball device includes a friction plate rockably supported having opening in which a top portion of the sphere is exposed, as a brake unit applying braking force (friction force) to the sphere, and an actuator capable of driving the friction plate to a lower side. When the friction plate is driven by the actuator, the circumference portion of the opening of the friction plate is pressed to be in contact with the sphere from an upper side. A supporting member rotatably holding the sphere includes a plurality of supporting small spheres contacts the sphere at a point and a base member in which the supporting small spheres is arranged to be dispersed in the circumferential direction. The base member rockably supports the friction plate.

### CLAIM OF PRIORITY

This application claims benefit of Japanese Patent Application No. 2010-180997 filed on Aug. 12, 2010, the entire contents of which is hereby incorporated by reference.

### BACKGROUND OF THE DISCLOSURE

1. Field of the Disclosure The present disclosure relates to an operation feeling imparting type trackball device that is suitable for an input device such as various kinds of electronic equipment or electronic devices loaded on a vehicle.

2. Description of the Related Art

In the related art, as described in for example, Japanese Unexamined Patent Application Publication No. 2009-128963, an operation feeling imparting type trackball device is known, in which when a user operates to rotate a sphere (a trackball) that is rotatably supported on a supporting member, a sensor detects a rotation direction and a rotation amount of the sphere and outputs a predetermined signal, and a braking force is applied to the sphere by a control based on the detection result of the sensor. In the type of trackball device, when a brake unit applies a braking force to the sphere by a control of a control unit, a rotational operation force that is required to rotate the sphere increases so that the operation feeling such as a click touch can be imparted to the user at an appropriate timing when the detection result of the sensor is reflected.

FIG. 7 is a drawing to explain a brake unit of the related art that is disclosed in Japanese Unexamined Patent Application Publication No. 2009-128963. In a trackball device 20 shown in the drawing, a sphere 21 is loaded on a recess surface of a supporting member 22 and is rotatably supported thereon. An actuator 23 such as a solenoid is capable of driving the supporting member 22 through a plunger 23a in the vertical direction. A top portion of the sphere 21 is exposed to the upper side of an opening 24a of a friction member 24. The friction member 24 is a circular ring-shaped member that is formed of a material where a friction resistance is easily generated. Also the friction member 24 is fixed to an upper lid 25 that forms one portion of a housing. A sensor 26 detects the rotation state (the rotation direction or the rotation amount) of the sphere 21 according to the rotational operation by the user and the detection signal is processed at a control unit (not shown). Also, the control unit controls the actuator 23 and drives the plunger 23a to the upper side if required.

In other words, the brake unit of the trackball device 20 of the related art as shown in FIG. 7 is constituted by the actuator 23 that is capable of moving the supporting member 22 vertically and the friction member 24 that is capable of pinching the sphere 21 cooperating with the supporting member 22. Thus, when the actuator 23 drives the supporting member 22 through the plunger 23a in the upper direction, the sphere 21 is pressed to be in contact with the friction member 24 at the circumference portion of an exposed portion thereof and a friction force is generated so that the braking is applied to the sphere 21 by the friction force at the time of rotational operation. If such a brake unit is employed, the device has advantages in which a relatively large braking force is capable of being generated and the structure thereof is comparatively simple.

However, in the trackball device 20 of the related art that employs the brake unit shown in FIG. 7, when the braking force (the friction force) is applied to the sphere 21 at the time of rotational operation, the supporting member 22 pushes the sphere 21 to the upper side and the sphere 21 is pressed to be in contact with the friction member 24 so that the sphere 21 that is exposed into the opening 24a of the friction member 24 slightly slides and moves to upper side. The amount of the sliding and moving itself is not especially large; however, the sliding and moving of the sphere 21 is clearly felt by the fingers of the user rotating and operating the sphere 21 (moving upward). Thus, the sliding and moving of the sphere 21 creates a sense of disharmony or displeasure in the user in the midst of operation, and this causes a decrease in the operation quality.

These and other drawbacks exist.

### SUMMARY OF THE DISCLOSURE

An advantage of the present disclosure is to provide an operation feeling imparting type trackball device in which there is no concern that the sphere will slide and move at the time of braking.

Accordingly, there is provided an operation feeling imparting type trackball device including: a sphere; a supporting member rotatably holding the sphere; a brake unit capable of applying a braking force to the sphere; a sensor detecting a rotation state of the sphere and outputing a detecting signal; and a control unit controlling the driving of the brake unit based on the detecting signal, wherein the sphere having a top portion exposed in rotatably operated, and wherein the brake unit is constituted by a friction member having an opening that exposes one portion of the sphere to an upper side and an actuator capable of driving the friction member to a lower side, and the actuator drives the friction member to a lower side so that the circumference portion of the opening is pressed to be in contact with the sphere from an upper side.

In the trackball device according to the configuration, when the actuator drives the friction member to the lower side, the circumference portion of the opening of the friction member is pressed to be in contact with the sphere that is retained at the supporting member and the braking force (the friction force) that resists against the rotational operation force is applied to the sphere. In other words, in a state in which the supporting member is fixed, the friction member moves to the lower side and the sphere is pinched and braked between both members so that the sphere is held in the same position both at the time of braking and at the time of non-braking. Accordingly, there is no concern that a sense of disharmony or displeasure will be created in the user in the midst of rotation operation and good operation quality is always capable of being maintained.

In the device according to the aspect of the invention, the friction member may be made of a planar body that is rockably supported one side thereof as the rotational center, and the other side of the friction member may be connected to the actuator and the opening substantially moves in the vertical direction according to the rocking of the friction member. Thus, the moving space of the friction member of the planar (the friction plate) is capable of being suppressed so that the trackball device is capable of easily realizing the compact size. In such a device, the supporting member may be constituted by a plurality of supporting small spheres that contacts the sphere at a point and a base member that disperses and arranges the supporting small spheres, and the base member may rockably support the friction member. Thus, the sphere is always stably retained and the positional accuracy of the friction member with respect to the sphere is easily increased.

The device may further include a lid that is fixed at a position where the lid covers the friction member, wherein the lid may have an upper opening of which the diameter is smaller than that of the opening of the friction member and the upper opening may be arranged concentrically at the upper portion of the opening. Thus, even if the position of the friction member varies at the time of the braking, there is no concern that the user will see the variation.

According to the operation feeling imparting type trackball device, since the sphere to which brake force (friction) can be applied is pinched using both members by causing the friction member to move downward as it is, the sphere is held in the same position both at the time of braking and at the time of non-braking. Further, it is possible to prevent the sphere from slide-moving, and good operation quality may be always expected.

### BRIEF DESCRIPTION OF THE DRAWINGS

FIG. 1 shows a perspective view illustrating an exterior shape of a trackball device according to an embodiment of the disclosure.

FIG. 2 shows a perspective view illustrating the trackball device of FIG. 1, wherein a lid is removed.

FIG. 3 shows a perspective view illustrating the trackball device of FIG. 2, wherein a housing is removed.

FIG. 4 shows an exploded perspective view illustrating a trackball device according to an embodiment of the disclosure.

FIG. 5 shows a vertical sectional view illustrating an exemplary trackball device taken along the longitudinal direction.

FIG. 6 shows a vertical sectional view illustrating an exemplary trackball device taken along the lateral direction.

FIG. 7 shows a drawing explaining the related art.

### DETAILED DESCRIPTION OF THE DISCLOSURE

The following description is intended to convey a thorough understanding of the embodiments described by providing a number of specific embodiments and details involving a trackball device. It should be appreciated, however, that the present invention is not limited to these specific embodiments and details, which are exemplary only. It is further understood that one possessing ordinary skill in the art, in light of known systems and methods, would appreciate the use of the invention for its intended purposes and benefits in any number of alternative embodiments, depending on specific design and other needs.

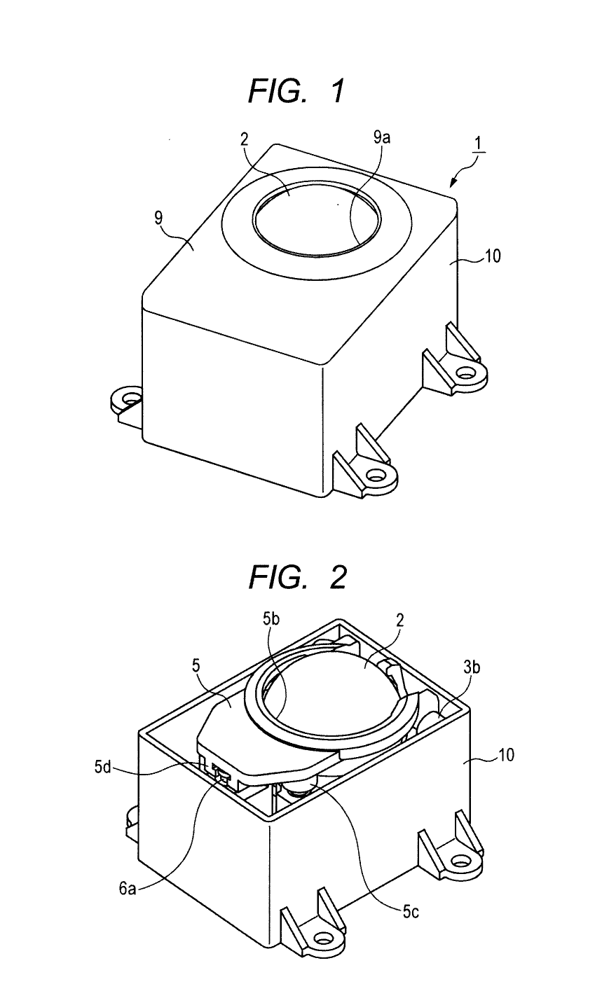

Hereinafter, embodiments of the disclosure are described with reference to FIGS. 1 to 6. A trackball device 1 illustrated in the drawings may be used as an input device of various kinds of electronic equipment (a computer equipment, an audio equipment or the like) or an input device of an electronic device loaded on a vehicle such as a car navigation device. A sphere 2 that may be made of metal or synthetic resin is rotatably (e.g., rotation about the center of the sphere) assembled in the trackball device 1 and a user may rotate the sphere 2 so that a signal is output according to a rotation state (a rotation direction or a rotation amount) of the sphere 2.

In various exemplary embodiments, almost all of the lower half of the sphere 2 may be inserted at a hollow section 3a of a base member 3. A plurality of supporting small spheres 4 that may be dispersed and arranged at a bowl-shaped inner wall surface of the hollow section 3a contacts the sphere 2 at a point. The supporting small spheres 4 may be made of synthetic resin or metal. In the embodiment, three supporting small spheres 4 may be arranged at the circumferential direction thereof at equal intervals; however, the supporting small spheres 4 may be four or more. A pair of bearing sections 3b may be arranged to be upright at the upper surface of one side of the base member 3. A supporting shaft 5a of a friction plate 5 may be pivoted at the bearing sections 3b. Also, an actuator 6 that may be formed of a solenoid may be attached at the other side of the base member 3 and an image sensor 7 may be attached at the bottom portion of the base member 3. Also, the supporting members that rotatably retain the sphere 2 may be constituted by the base member 3 and each of the supporting small spheres 4.

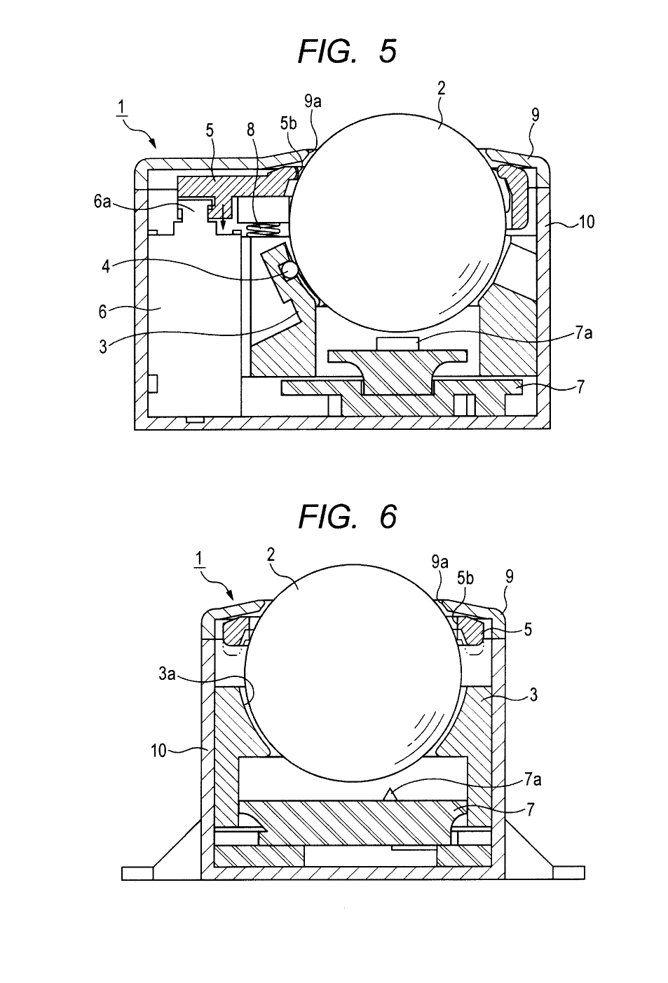

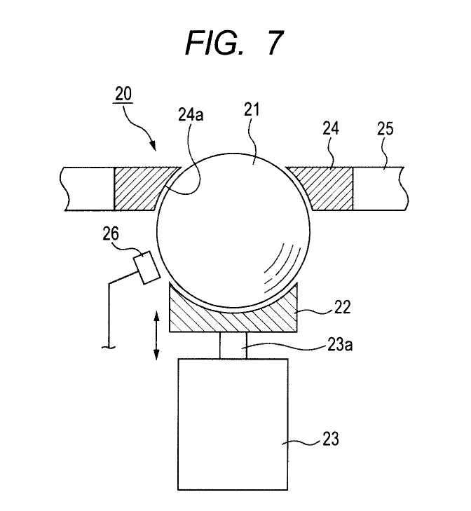

The friction plate 5 may be a planar-shaped member that may be made of a material where the friction resistance is easily generated. The friction plate 5 may be rockably supported at the base member 3 about the pair of the supporting shaft 5a as the rotation shaft that may be projected at one side thereof. An opening 5b, spring receiving sections 5c and the driven section 5d may be provided at the friction plate 5 besides the supporting shaft 5a. The top portion of the sphere 2 may be exposed from the opening 5b and projected toward the upper side. Upper end portions of a pair of coil springs 8 may be inserted in the spring receiving sections 5c of the friction plate 5 respectively and the friction plate 5 may be urged against the upper side by the elastic forces of the coil springs 8. An upper end portion of a plunger 6a of an actuator 6 may be engaged in the driven section 5d of the friction plate 5. The driven section 5d may be connected to the plunger 6a at the side portion that is the reverse side of the supporting shaft 5a of the friction plate 5. As shown in FIGS. 5 and 6, when electric current does not pass through the actuator 6, the friction plate 5 that receives the elastic forces of the coil springs 8 and is biased to the upper side so that the friction plate 5 may be retained in a substantially horizontal position that is not in contact with the sphere 2. Thus, when the electric current does pass through the actuator 6 and the plunger 6a moves to the lower side, the friction plate 5 may be driven by the plunger 6a in an arrow direction as shown in FIG. 5, so that the circumference portion of the opening 5b is pressed and contacted with respect to the sphere 2, and a braking force (a friction force) is applied to the sphere 2 as shown in the two dot chain line in FIG. 6. In other words, the brake unit that applies the braking force to the sphere 2 may be configured of the friction plate 5 and the actuator 6.

An image sensor 7 may be a known optical sensor that illuminates the detecting light to the surface of the sphere 2 through a lens 7a and may receive a reflecting light through the lens 7a and then may detect the rotation direction and the rotation amount of the sphere 2 in real time.

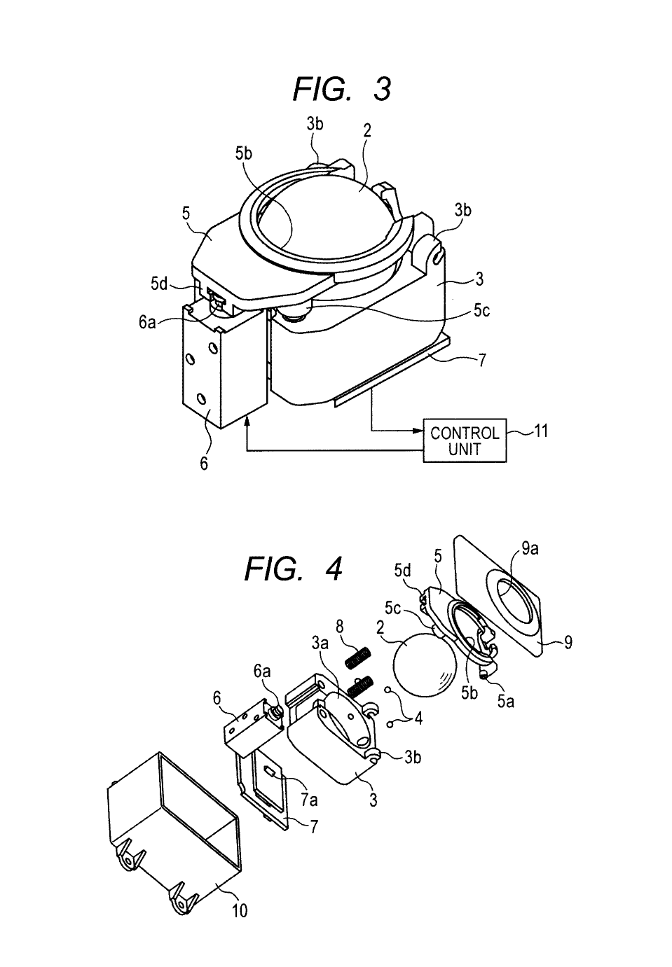

As shown in FIG. 3, the sphere 2 that is retained at the supporting members (the base member 3 and each of the supporting small spheres 4), the friction plate 5 that is attached to the base member 3, the actuator 6 and the image sensor 7 may be unitized. Since the unit may be accommodated in a housing 10 having a lid 9 and then the top portion of the sphere 2 may be projected to the outside from an upper opening 9a of the lid 9, the user may be capable of rotatably operating the top portion of the sphere 2 that is projected from the upper opening 9a with his or her fingers. Also, the upper opening 9a of the lid 9 has a diameter smaller than the opening 5b of the friction plate 5 and the upper opening 9a may be arranged at the upper side of the opening 5b concentrically.

Also, as shown in FIG. 3, the actuator 6 and the image sensor 7 may be connected to a control unit 11 through a cable or the like (not shown). The control unit 11 may be a microcomputer having a central processing unit (CPU), a ROM a RAM and the like. The signal that is detected by the image sensor 7 may be processed at the control unit 11 so that the content of rotational operation that is performed with respect to the sphere 2 may be identified. Also, the control unit 11 may control the driving of the actuator 6 and then the plunger 6a may be capable of being moved in the lower side if required.

In the above-described trackball device 1, when the user rotates the top portion of the sphere 2 that is projected to the upper opening 9a of the lid 9, the image sensor 7 may detect the rotation state (the rotation direction or the rotation amount) of the sphere 2 and outputs the detecting signal to the control unit 11. The control unit 11 may process the detecting signal and may identify the contents of the rotational operation of the sphere 2 by the user. The control signal may be output to the electronic equipment or the electronic device loaded on the vehicle where the trackball device 1 is used as the input device based on the result of the process. Accordingly, an input operation, for example, change of a position of a cursor that may be expressed at the display according to the rotational operation with respect to the sphere 2, is performed.

The trackball device 1 may put the actuator 6 in the conductive state at an appropriate timing in which the detecting result of the image sensor 7 may be reflected and the plunger 6a may move to the lower side so that at this time, the friction plate 5 that is driven by the plunger 6a is pressed to contact with the sphere 2 and the braking force (the friction force) that resists the rotational operation force may be generated. For example, the cursor on the display may move to a predetermined position, the braking force may be applied to the sphere 2 so that the finger of the user is capable of feeing the operation feeling such as click touch. As described above, when the conductivity is not applied to the actuator 6, the friction plate 5 may be maintained in a substantially horizontal position that is not in contact with the sphere 2.

As described above, in the trackball device 1 according to the embodiment, when the plunger 6a of the actuator 6 drives the friction plate 5 to the lower side, the circumference portion of the opening 5b of the friction plate 5 may be pressed to be in contact with the sphere 2 that is retained at the supporting members (the base member 3 and each of the supporting small spheres 4) from the upper side, so that the braking force (the friction force) may be applied to the sphere 2 against the rotational operation force. In other words, the friction plate 5 may move to the lower side in a state where the supporting members are fixed. Thus, since the sphere 2 is pressed and braked between each of the supporting small spheres 4 and the friction plate 5, the sphere 2 may be retained at the same position at both of the time of braking and the time of non-braking. Accordingly, a sense of disharmony or displeasure is not created in the user in the midst of operation due to the sphere that moves to the upper side at the time of braking, and the trackball device 1 may be capable of maintaining a good operational quality.

Also, in the trackball device 1 according to the embodiment, the friction plate 5 having a planar body may be rockably supported about the supporting shaft 5a as a rotational center that is provided at one side thereof and the other side (the driven section 5d) that is the reverse side of the supporting shaft 5a is connected to the plunger 6a of the actuator 6 and the opening 5b moves substantially to the vertical direction according to the rocking of the friction plate 5. Thus, the moving space of the friction plate 5 may be capable of being suppressed and the trackball device 1 may be capable of easily realizing the compact size.

Additionally, in the trackball device 1 according to the embodiment, the supporting members that rotatably support the sphere 2 may be constituted by a plurality of the supporting small spheres 4 that may contact the sphere 2 at a point and the base member 3 where the supporting small spheres 4 are dispersed and arranged in circumferential direction, and the base member 3 may rockably support the friction plate 5 so that the sphere 2 may be stably retained and the positional accuracy of the friction plate 5 with respect to the sphere 2 is easily increased.

Also, in the trackball device 1 according to the embodiment, the lid having the upper opening 9a of which the diameter may be smaller than that of the opening 5b is fixed at a position where the friction plate 5 is covered. The upper opening 9a may be arranged on upper side of the opening 5b concentrically so that even if the position of the friction plate 5 varies at the time of the braking, there is no concern that the user will see the variation and a sense of visual disharmony can be avoided.

Also, in the above-described embodiment, the image sensor 7 as a sensor that detects the rotation state of the sphere 2 may be used; however, another optical sensor, electromagnetic sensor or the like may be used.

Additionally, in the above-described embodiment, the rockable friction plate 5 as the friction member that is pressed to be in contact with the sphere 2 may be used; however, a friction member having a non-planar shape may be used or a friction member that is not rockable but movable in the vertical direction may be used.

It should be understood by those skilled in the art that various modifications, combinations, sub-combinations and alterations may occur depending on design requirements and other factors insofar as they are within the scope of the appended claims of the equivalents thereof.

Accordingly, the embodiments of the present inventions are not to be limited in scope by the specific embodiments described herein. Further, although some of the embodiments of the present invention have been described herein in the context of a particular implementation in a particular environment for a particular purpose, those of ordinary skill in the art should recognize that its usefulness is not limited thereto and that the embodiments of the present inventions can be beneficially implemented in any number of environments for any number of purposes. Accordingly, the claims set forth below should be construed in view of the full breadth and spirit of the embodiments of the present inventions as disclosed herein. While the foregoing description includes many details and specificities, it is to be understood that these have been included for purposes of explanation only, and are not to be interpreted as limitations of the invention. Many modifications to the embodiments described above can be made without departing from the spirit and scope of the invention.

What is claimed is:

1. An operation feeling imparting type trackball device comprising:
a sphere;
a supporting member rotatably holding the sphere;
a brake unit capable of applying a braking force to the sphere;
a sensor detecting a rotation state of the sphere and outputting a detecting signal; and
a control unit controlling the driving of the brake unit based on the detecting signal,
wherein the sphere having a top portion exposed in rotatably operated, and
wherein the brake unit includes a friction member having an opening that exposes one portion of the sphere to an upper side and an actuator capable of driving the friction member to a lower side, and
the actuator drives the friction member to a lower side so that the circumference portion of the opening is pressed to be in contact with the sphere from an upper side.

2. The operation feeling imparting type trackball device according to claim 1, wherein the friction member comprises a planar body that is rockably supported one side thereof as the rotational center and the other side of the friction member is connected to the actuator and the opening substantially moves in the vertical direction according to the rocking of the friction member.

3. The operation feeling imparting type trackball device according to claim 2, wherein the supporting member includes a plurality of supporting small spheres that contacts the sphere at a point and a base member that disperses and arranges the supporting small spheres, and the base member rockably supports the friction member.

4. The operation feeling imparting type trackball device according to claim 1, further comprising a lid that is fixed at a position where the lid covers the friction member,
wherein the lid has an upper opening of which the diameter is smaller than that of the opening and the upper opening is arranged concentrically at the upper portion of the opening.
